(19) United States
(12) Patent Application Publication
(10) Pub. No.: US 2019/0206833 A1
(43) Pub. Date: Jul. 4, 2019

(54) EPLB/EWLB BASED POP FOR HBM OR CUSTOMIZED PACKAGE STACK

(71) Applicant: Intel IP Corporation, Santa Clara, CA (US)

(72) Inventors: Thorsten MEYER, Regensburg (DE); Klaus REINGRUBER, Langquaid (DE); Georg SEIDEMANN, Landshut (DE); Andreas WOLTER, Regensburg (DE); Christian GEISSLER, Teugn (DE); Sven ALBERS, Regensburg (DE)

(21) Appl. No.: 15/772,730

(22) PCT Filed: Dec. 23, 2015
(86) PCT No.: PCT/US2015/000291

§ 371 Date: May 1, 2018

(51) Int. Cl. H01L 25/065; H01L 23/31; H01L 23/538; H01L 23/00; H01L 23/498; H01L 21/56; H01L 21/48

(52) U.S. Cl. CPC H01L 25/0652; H01L 23/3128; H01L 23/5389; H01L 24/12; H01L 24/32; H01L 23/49827; H01L 2924/19105; H01L 21/4853; H01L 2225/06548; H01L 2224/12105; H01L 2224/32225; H01L 2224/16227; H01L 21/568

(57) ABSTRACT

Embodiments of the invention include an eWLB or ePLB based PoP device and methods of forming such devices. According to an embodiment, such a device may include a die embedded within a mold layer. A substrate may be directly contacting a surface of the mold layer. Additionally, embodiments of the invention may include a through mold via formed through the mold layer that is electrically coupled to a contact formed on a surface of the substrate that is contacting the mold layer. In order to form such a device, embodiments may include dispensing a molding material over a die positioned on a mold carrier. Thereafter, a substrate may be pressed into the molding material. After curing the molding material, a mold layer may be formed that encases the die and is adhered to the substrate.

### FIELD OF THE INVENTION

Embodiments of the present invention relate generally to the manufacture of semiconductor devices. In particular, embodiments of the present invention relate to package on package (PoP) devices and methods for manufacturing such devices.

### BACKGROUND OF THE INVENTION

Package on package (PoP) stacking is an important system in package (SiP) solution in the area of mobile applications. In the mobile applications world, the height of stacked packages is an important driver for new applications. Reducing the height of packages may allow for them to fit in thinner mobile devices or at new positions within the mobile device (e. g. under battery, double sided assembly of a board, etc.). Accordingly, future system integration applications are currently driving to further reduce the thickness of PoP solutions.

One current PoP solution may include the use of embedded wafer level ball grid array (eWLB) or embedded panel level ball grid array (ePLB) technologies. Such a PoP device based on eWLB technology is illustrated in the cross-sectional view in FIG. 1. The PoP device includes a die 110 that is embedded within a mold layer 115 and a substrate 135 stacked over the mold layer 115. A redistribution layer 130 may be formed on the bottom surface of the mold layer 115. Typically a redistribution layer 130 may include conductive lines and vias 132 formed in one or more dielectric layers 134. Vias 125 may be formed through the mold layer 115 in order to provide conductive paths between the top and bottom surfaces of the mold layer 115.

The substrate 135 mounted over the mold layer 115 may include any number of active or passive components 140. In some instances, a second mold layer 116 may also encase the components. A second die 120 may also be mounted to the second substrate 135. The second die 120 may be any die, such as a power management integrated circuit (PMIC) or a memory component, such as a high bandwidth memory (HBM). However, mounting the substrate 135 to the mold layer 115 increases the thickness of the PoP device. For example, the substrate 135 needs to be electrically and mechanically coupled to the vias 125 in the mold layer 115 by solder bumps 126. The solder bumps 126 have a stand-off height T that increases the thickness of the package. For example, the solder bumps 126 may have a stand-off height T that is approximately 50 μm or greater. In addition to the increase in height attributable to the solder bumps 126, the assembly process provides additional drawbacks that prevent further reduction of the thickness of eWLB/ePLB based PoP devices. Specifically, the substrate 135 needs to be attached with the solder bumps 126 after the lower package is formed. Therefore, the mold layer 115 of the eWLB/ePLB (which may also be referred to as a reconstituted wafer or panel) needs to be able to withstand the stresses of package assembly. Accordingly, the mold layer 115 needs to be relatively thick. As such, the overall package thickness needs to be increased in order to assemble the PoP device.

Accordingly, there is a need in the art for packaging technologies that allow for the formation of thin PoP devices.

### BRIEF DESCRIPTION OF THE DRAWINGS

FIG. 1 is a cross-sectional illustration of a eWLB/ePLB based PoP device.

FIG. 2A is a cross-sectional illustration of a semiconductor package that includes a mold layer that includes through mold vias that is mounted directly to a substrate without solder bumps, according to an embodiment of the invention.

FIG. 2B is a cross-sectional illustration of a semiconductor package that includes a mold layer with through mold vias that include conductive balls that is mounted directly to a substrate without solder bumps, according to an embodiment of the invention.

FIG. 2C is a cross-sectional illustration of a semiconductor package that includes a mold layer with through mold vias and embedded components that is mounted directly to a substrate without solder bumps, according to an embodiment of the invention.

FIG. 2D is a cross-sectional illustration of a semiconductor package that includes a mold layer with through mold vias and a die that includes conductive pillars that is mounted directly to a substrate without solder bumps, according to an embodiment of the invention.

FIG. 3A is cross-sectional view of a plurality of dice on a mold carrier in a molding tool used to simultaneously form a mold layer and attach a substrate, according to an embodiment of the invention.

FIG. 3B is a cross-sectional view of a portion of the mold layer and substrate after the substrate carrier is removed from the molding tool, according to an embodiment of the invention.

FIG. 3C is a cross-sectional view of the package after the carrier substrate and adhesive are removed from the mold layer, according to an embodiment of the invention.

FIG. 3D is a cross-sectional view of the package after via openings are formed through the mold layer, according to an embodiment of the invention.

FIG. 3E is a cross-sectional view of the package after through mold vias are formed in the via openings, according to an embodiment of the invention.

FIG. 3F is a cross-sectional view of the package after a redistribution layer is formed over the surface of the mold layer, according to an embodiment of the invention.

FIG. 3G is a cross-sectional view of the package after components and solder bumps are mounted to the package, according to an embodiment of the invention.

FIG. 4A is a cross-sectional view of a die on a mold carrier in a molding tool used to simultaneously form a mold layer and attach a substrate with conductive balls to the mold layer, according to an embodiment of the invention.

FIG. 4B is a cross-sectional view of the package after it has been removed from the molding tool, according to an embodiment of the invention.

FIG. 4C is a cross-sectional view of the package after via openings are formed through the mold layer to expose the conductive balls, according to an embodiment of the invention.

FIG. 4D is a cross-sectional view of the package after through mold vias are formed in the via openings, according to an embodiment of the invention.

FIG. 5A is a cross-sectional view of a die on a mold carrier in a molding tool used to simultaneously form a mold layer and attach a substrate with components to the mold layer, according to an embodiment of the invention.

FIG. 5B is a cross-sectional view of the package after it has been removed from the molding tool, according to an embodiment of the invention.

FIG. 6A is a cross-sectional view of a die attached to a substrate being embedded in a mold layer, according to an embodiment of the invention.

FIG. 6B is a cross-sectional view of the package after it has been removed from the molding tool and the adhesive is removed from the package, according to an embodiment of the invention.

FIG. 6C is a cross-sectional illustration of the package after the mold layer has been recessed to expose conductive pillars and the through mold vias are formed, according to an embodiment of the invention.

FIG. 7 is a schematic of a computing device built in accordance with an embodiment of the invention.

### DETAILED DESCRIPTION OF THE INVENTION

Described herein are systems that include a semiconductor package and methods of forming such semiconductor packages. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

In order to decrease the overall thickness of the package, embodiments of the invention include a mold layer and a substrate that are stacked without the need for solder bumps to electrically and mechanically couple the two together. Instead of forming a reconfigured wafer or panel and then attaching the substrate to the mold layer with solder bumps, embodiments of the invention mount the substrate directly to the mold layer during the molding process. As such, the extra stand-off height needed for the solder bumps is eliminated. By way of example, the elimination of solder bumps may reduce the thickness of the package by approximately 50 μm or more. Additionally, mounting the substrate directly to the mold layer allows for a thinner mold layer to be formed. Since the substrate provides mechanical stability during subsequent processing (e.g., during handling and through mold via formation) the thickness of the mold layer may be decreased relative to the mold layers used in typical eWLB/ePLB processes. Therefore, embodiments of the invention are able to provide PoP devices that have reduced thicknesses because the solder bumps between the mold layer and the substrate are eliminated, and because the thickness of the mold layer may be reduced.

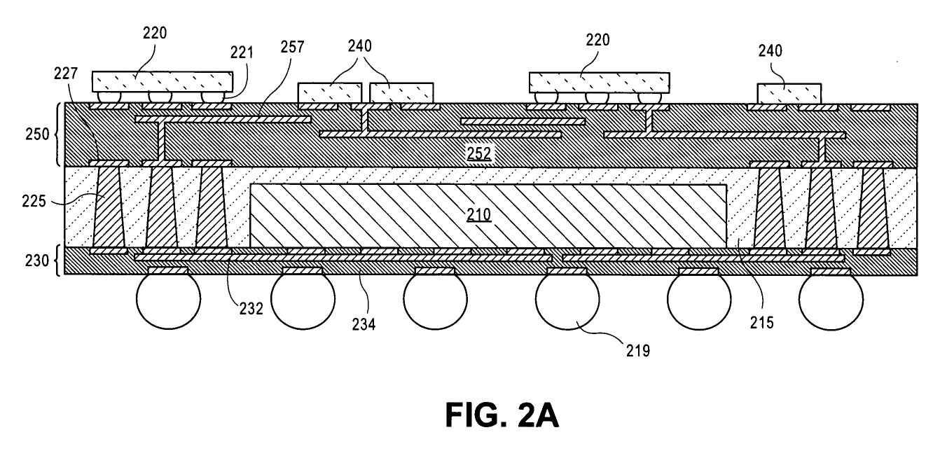

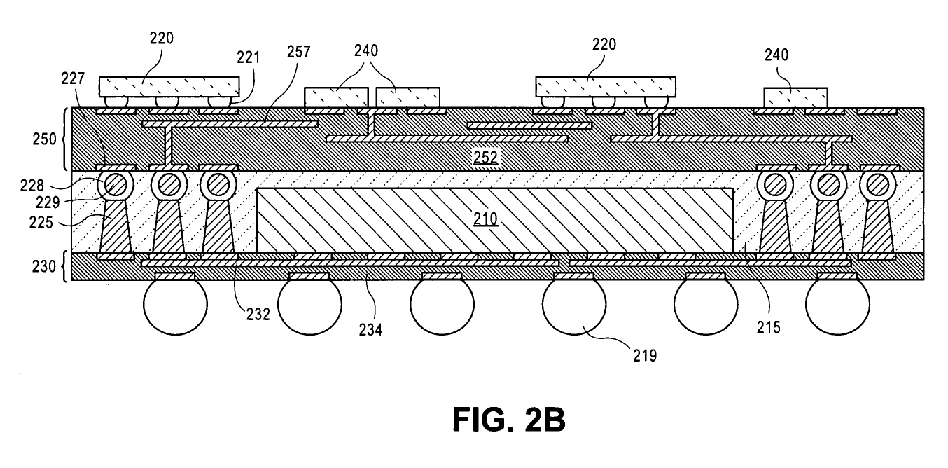

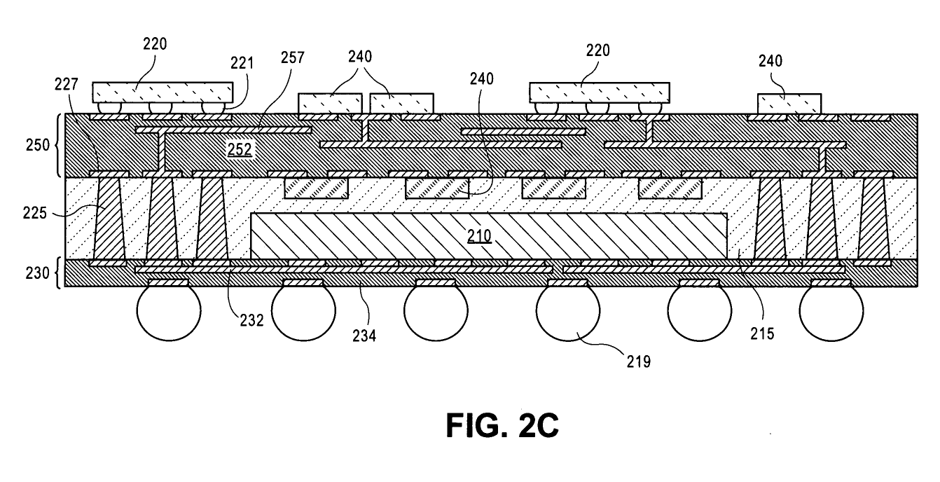

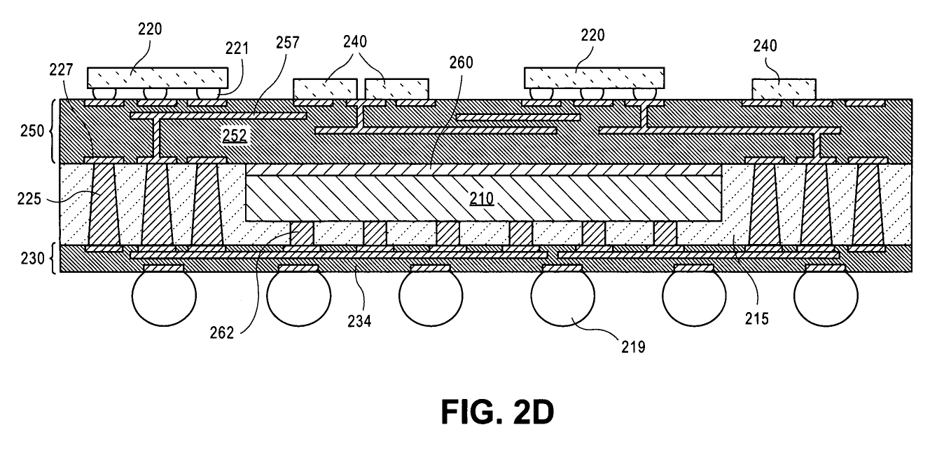

Embodiments of the invention include a plurality of different configurations that may be used separately or in combination, depending on the needs of the device. Some exemplary configurations according to embodiments of the invention are illustrated in FIGS. 2A-2D.

Referring now to FIG. 2A, a cross-sectional illustration of a package is shown according to an embodiment of the invention. The package may include a die 210 that is encapsulated within a mold layer 215. According to an embodiment, the mold layer 215 may be any suitable molding material. By way of example, the mold layer 215 may be a polymeric material or an epoxy. In an embodiment, the mold layer 215 may be filled with filler particles, made of silicon, glass or the like. The die 210 may be any desired component, such as an integrated circuit (IC) (e.g., a microprocessor, a graphics processor, or the like). While a single die 210 is illustrated as being embedded in the mold layer 215, embodiments are not limited to such configurations. For example, any number of dice 210 may be embedded in the mold layer 215.

According to an embodiment, a redistribution layer 230 may be formed over a surface of the mold layer 215. The redistribution layer 230 may include one or more dielectric film layers 234 and conductive traces and vias 232. Additional embodiments may also include solder resists (not shown) formed over a surface of the redistribution layer 230 in order to prevent solder bumps 219 from shorting between contacts. The conductive traces and vias 232 provide electrical routing from the die 210 to the solder bumps. The conductive traces may also electrically couple through mold vias 225, to the die 210 and/or the solder bumps 219.

According to an embodiment of the invention, the through mold vias 225 may be a conductive material that extends through a thickness of the mold layer 215. In the illustrated embodiment, the through mold vias 225 are shown having tapered sidewalls. Embodiments of the invention may include tapered sidewalls when a laser drilling process is used to form the openings in which the through mold vias 225 are formed. However, it is to be appreciated that the shape of the through mold vias does not need to include continuously tapered sidewalls. As will be described in greater detail below, alternative fabrication processes may be used that produce through mold vias that have alternative sidewall shapes. The through mold vias 225, provide electrical pathways from one surface of the mold layer 215 to the opposite surface of the mold layer 215. This enables a substrate 250 to be mounted above the mold layer 215. According to an embodiment, the active side of the embedded die 210 may oriented so that it faces away from the substrate 250.

According to an embodiment, the substrate 250 is mounted directly to a surface of the mold layer 215 without the need for solder bumps. As illustrated, contacts 227 in the substrate 250 may be in direct contact with a surface of the through mold vias 225. According to an embodiment, the adhesion between the substrate 250 and the mold layer 215 is sufficiently strong enough to provide a mechanical bond between the two layers. The adhesion between the two layers is sufficiently strong because the substrate 250 may be bonded to the mold layer 215 during the molding process used to form the mold layer, as will be described in greater detail below. Additional embodiments of the invention may further increase the adhesion between the substrate 250 and the mold layer 215 by including mechanical anchors (not shown) on the substrate 250. For example, the substrate 250 may also include ridges, grooves, pockets, or the like in order to further increase the adhesion between the two layers.

According to an embodiment, the substrate 250 may include conductive traces and vias 257 formed in one or more dielectric layers 252. By way of example, the dielectric layers may be a polyimide, polybenzoxazole (PBO), ABF, or epoxy based material. The conductive traces and vias 257 may provide electrical routing from the contacts 227 to one or more components 220/240 mounted to the substrate 250. The components 220 are illustrated as being mounted to conductive traces with solder bumps 221. For example, the components 220 may be flip-chip mounted to the substrate 250. In one embodiment the components 220 may be a die or the like. For example, the components may be a memory device, such as a high bandwidth memory (HBM) device, a power management integrated circuit (PMIC), or the like. Other components 240 are illustrated as being directly mounted to the substrate 250 without solder bumps. The additional components 240 may be active or passive components. For example, active electronic components may include one or more semiconductive dies with integrated circuitry, such as transistors, diodes, or the like, and passive electronic components may include resistors, capacitors, integrated passive devices (IPDs), or the like.

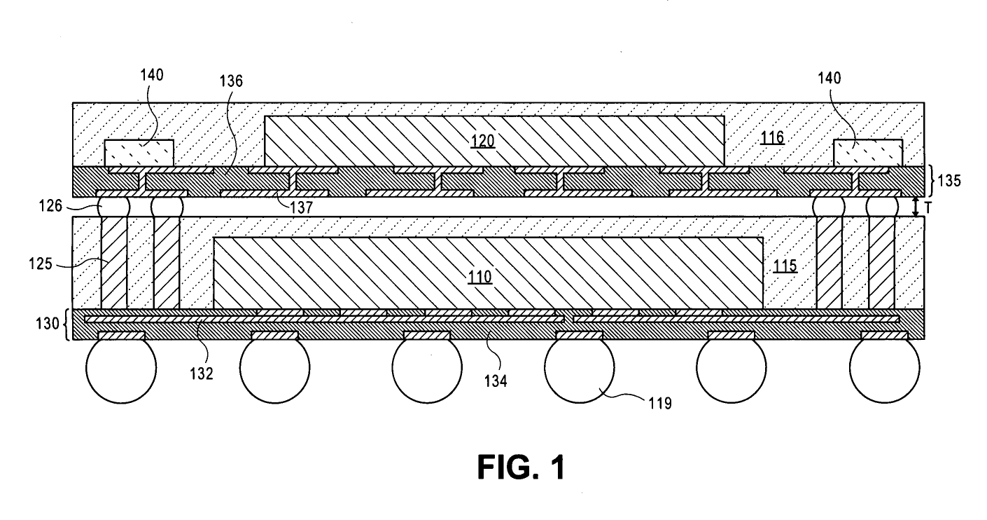

Accordingly, the packaged device according to the embodiment illustrated in FIG. 2A may be relatively thinner than the other ePLB/eWLB based PoP devices, such as those described with respect to FIG. 1, because there is no need for solder bumps between the mold layer 215 and the substrate 250 of the second package. According to an embodiment, the overall thickness of the PoP device may be reduced 50 μm or more compared to standard ePLB/eWLB based PoP devices.

As mentioned above, additional embodiments of the invention may also include through mold vias that do not have continuously tapered sidewalls throughout the entire thickness of the mold layer 215. A package according to such an embodiment is illustrated and described with respect to FIG. 2B.

As illustrated in FIG. 2B, the through mold vias 225 do not extend completely through the mold layer 215. Instead, embodiments of the invention may also include conductive balls 228. The conductive balls 228 may electrically couple the through mold vias 225 to the pads 227 of the substrate 250. The conductive balls 228 may be any suitable conductive material. For example, the conductive balls 228 may be solder balls. Additional embodiments of the invention may include conductive balls 228 that have a core 229, as is shown in FIG. 2B. The core 229 may be a conductive or non-conductive material. For example, a solder ball 228 may have a copper core or a polymer core. Furthermore, while the conductive balls 228 are illustrated as being substantially round, it is to be appreciated that any shaped conductive element may be used. Additional embodiments may replace the conductive balls 228 with conductive pillars (e.g., copper pillars). In some embodiments conductive pillars may be substantially the same thickness as the mold layer 215. In such embodiments the laser drilled via openings may not be necessary.

The use of conductive balls 228 provides several benefits. One benefit is that the laser drilled openings for the vias 225 do not need to be as deep. As such, the throughput can be increased because the reduced drill depth reduces the time needed to form the via openings. Additionally, the shallower openings are easier to fill with conductive material. Accordingly, the yield may be increased because the openings are more likely to be properly filled with conductive material. Furthermore, the shallower drill depth allows for the vias 225 to be formed with a tighter pitch. Reducing the pitch allows for a decrease in the size of the package.

Referring now to FIG. 2C, a cross-sectional illustration of an additional embodiment of the invention is shown. According to an embodiment, one or more additional components 240 may be embedded in the mold layer 215. The additional components 240 may be electrically coupled to the pads formed on a bottom surface of the substrate 250. By way of example, the additional components may be passive devices or active devices. Positioning components on the bottom surface of the substrate 250 so that they are embedded in the mold layer provides additional surface area on the substrate for attaching needed components. As such, more components may be included than would otherwise be possible. Additional embodiments of the invention may include a package that has all components 240 formed on the bottom surface of the substrate 250 and embedded in the mold layer 215. By relocating components 240/220 from the top surface of the substrate 250 to the bottom surface of the substrate 250, the overall thickness of the package may be decreased.

Referring now to FIG. 2D, a cross-sectional illustration of another embodiment of the invention is shown. As illustrated, the die 210 may be attached to substrate 250. According to an embodiment, the die 210 may be attached to the substrate 250 with an adhesive layer 260. The die 210 may be attached to the substrate 250 so that the active side of the die 210 is facing away from the substrate 250. In such embodiments, the die 210 may be attached to the substrate 250 prior to forming the mold layer, as will be described in greater detail below. In order to allow for electrical connections to be made from the die 210 to the bottom surface of the mold layer 215, pillars 262 may be attached to the die 210. According to an embodiment, the pillars 262 may be copper pillars.

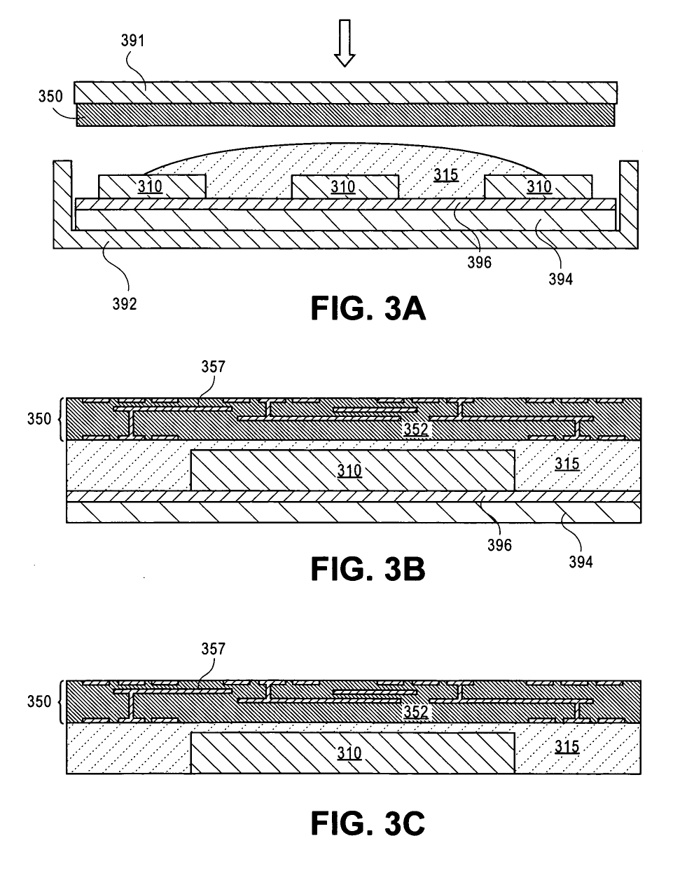

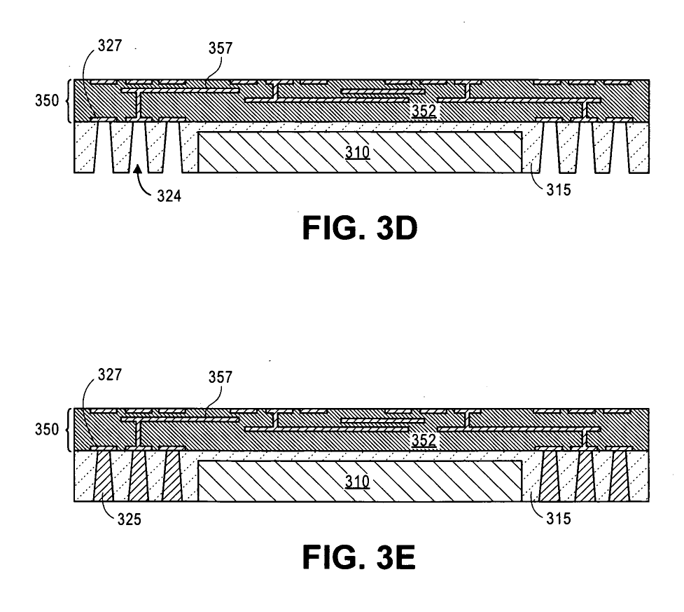

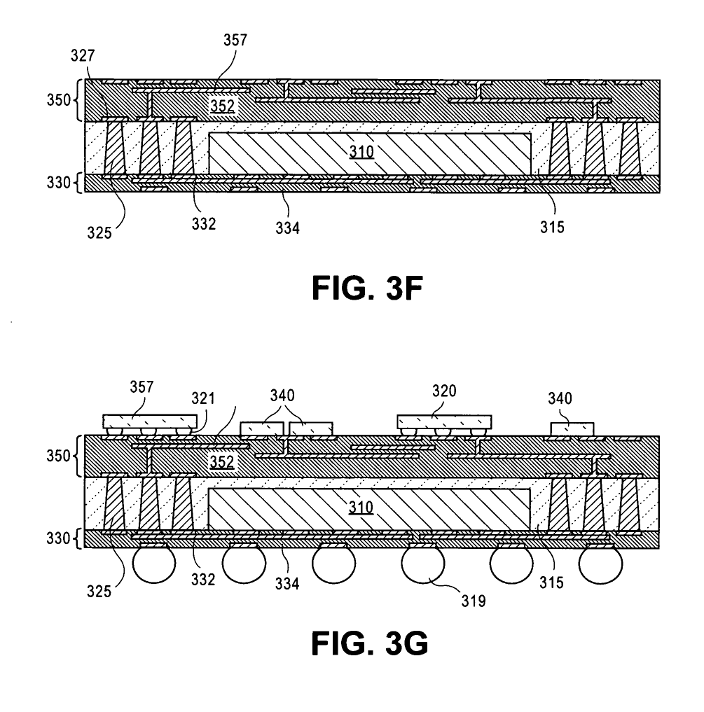

The ability to form packages according to embodiments of the invention is made possible by using a molding process that simultaneously mounts the substrate to the mold layer as the mold layer is being formed. A process flow for forming such packages according to an embodiment of the invention is illustrated and described with respect to FIGS. 3A-3G.

Referring now to FIG. 3A, a cross-sectional illustration of a molding tool that is used to form the mold layer and simultaneously mount the substrate to the mold layer is shown according to an embodiment of the invention. Embodiments of the invention include placing a plurality of dice 310 on a mold carrier 394. The dice 310 may be adhered to the mold carrier 394 with an adhesive layer 396. In an embodiment, the dice 310 are adhered to the mold carrier 394 with an active side of the dice 310 facing the mold carrier 394. While three dice 310 are illustrated in FIG. 3A, it is to be appreciated that any number of dice 310 may be mounted on the mold carrier 394. According to an embodiment, the dice 310 may be mounted on the mold carrier 394 with a pick and place tool.

After the dice 310 are mounted on the mold carrier 394, the mold carrier 394 may be placed in the molding tool. In one embodiment, the molding tool may include a supporting portion 392 for supporting the mold carrier 394 and a top portion 391 for holding the substrate 350. For example, the substrate 350 may be held in place with a vacuum. While the illustrated embodiment depicts a molding tool with two components, it is to be appreciated that any suitable molding tool that can support the mold carrier 394 and attach the substrate may be used. It is to be appreciated that the substrate 350 illustrated in FIG. 3A is shown without any conductive traces or pads in order to not unnecessarily obscure the Figure. As will be shown in zoomed in portions in subsequent Figures, embodiments include a substrate 350 that has conductive traces and pads already formed prior to mounting.

According to an embodiment, a molding compound 315 may be dispensed over the mold carrier 394 and the dice 310. By way of example, the molding compound 315 may be any suitable compound (e.g., liquid, granular, pellet, sheet, etc.). After the molding compound 315 is dispensed, the top portion 391 of the molding tool may be pressed into the molding compound 315, as indicated by the arrow. Pressing the top portion 391 of the molding tool brings the substrate 350 into contact with the molding compound. After a curing process, the substrate 350 may be adhered to the solidified mold layer 315.

Referring now to FIG. 3B, a cross-sectional illustration of one slot of the combined substrate 350 and mold layer 315 prior to the package being separated from the mold carrier 394 is shown according to an embodiment of the invention. It is to be appreciated that the slot shown may be a single slot in wafer (i.e., eWLB) or a panel (ePLB).

Referring now to FIG. 3C, a cross-sectional illustration of the package after the mold carrier 394 and the adhesive 396 are removed is shown according to an embodiment of the invention. Unlike standard eWLB or ePLB packages, the mold layer 315 is provided with additional mechanical stability by the substrate 350. Accordingly, further processing (e.g., handling the package and forming through mold vias) may be implemented without damaging that package even when the mold layer 315 has a relatively small thickness. For example, when a substrate 350 is not attached to the mold layer 315, the mold layer typically needs to be approximately 400 μm thick or greater.

Referring now to FIG. 3D, a cross-sectional illustration of the package after via openings 324 are formed is shown according to an embodiment of the invention. The via openings 324 may be formed through the entire thickness of the mold layer 315 in order to expose pads 327 on the bottom side of the substrate 350. By way of example, the via openings 324 may be formed with a laser drilling process. At this point those skilled in the art will recognize that the mold layer 315 may obscure any view of the pads 327 formed on the substrate 350 during the laser drilling process since the mold layer may be opaque. In order to form accurately aligned via openings 324, the position of the die 310 may be used as a reference for aligning the laser. Accordingly, the alignment of the die 310 with the substrate 350 should be accurate, otherwise the via openings 324 may be misaligned and not expose the desired pad. Typical pick and place tools used to mount the dies 310 to the mold carrier have an accuracy within +/−50 μm, which is generally sufficient to provide the desired alignment. According to an additional embodiment, optical alignment in the infrared (IR) spectrum may be used to align the via openings 324.

Referring now to FIG. 3E, a cross-sectional illustration of the package after the via openings 324 are filled with conductive material to form the through mold vias 325 is shown according to an embodiment of the invention. For example, the via openings 324 may be filled with any suitable deposition processes known in the art, such as electroplating, electroless plating, sputtering, printing, jetting, or any combination thereof.

Referring now to FIG. 3F, a cross-sectional illustration of the package after the redistribution layer 330 is formed is shown according to an embodiment of the invention. Embodiments of the invention may include depositing and patterning a dielectric material 334 alternating with a metal deposition process to form conductive traces and vias 332. In an embodiment, the patterning may be done via photo-lithography (e.g., mask aligner, or stepper) or laser (e.g., laser direct imaging (LDI) or laser removal). These processes may also include adaptive structuring of the redistribution layer in order to improve the alignment of contacts with the through mold vias 325. In an embodiment, the conductive traces and vias 332 may be formed with processes known in the art, such as electroplating, electroless plating, sputtering, printing, jetting, or any combination thereof. According to an embodiment, a solder resist (not shown) may also be formed over portions of the dielectric material 334 and the conductive traces 332. While the plating process for forming the through vias 325 and forming the redistribution layer 330 is illustrated and described as being distinct processing operations, embodiments of the invention are not limited to such configurations. For example, an electroplating process may be used to simultaneously plate the through vias 325 and the conductive features 332 of the redistribution layer 330.

Referring now to FIG. 3G, a cross-sectional illustration of the package after components 340/320 and solder bumps 319 have been attached is shown according to an embodiment of the invention. For example, the components 320 may be flip-chip mounted to the substrate 350 with solder bumps 321. In one embodiment the components 320 may be a die or the like. For example, the components may be a memory device, such as a HBM device, a PMIC, or the like. Other components 340 are illustrated as being directly mounted to the substrate 350 without solder bumps. The additional components 340 may be active or passive components. For example, active electronic components may include one or more semiconductive dies with integrated circuitry, such as transistors, diodes, or the like, and passive electronic components may include resistors, capacitors, IPDs, or the like.

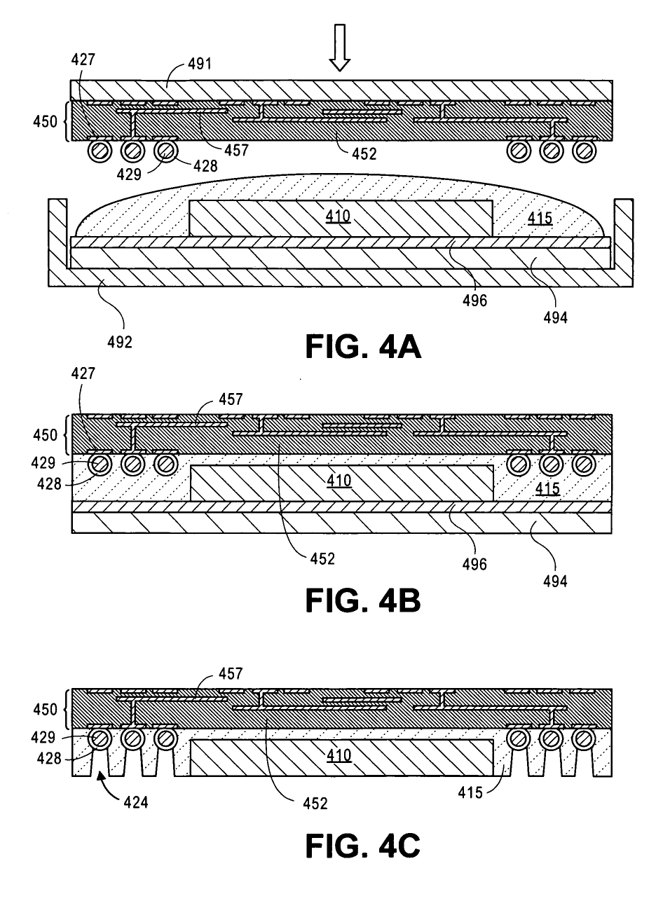

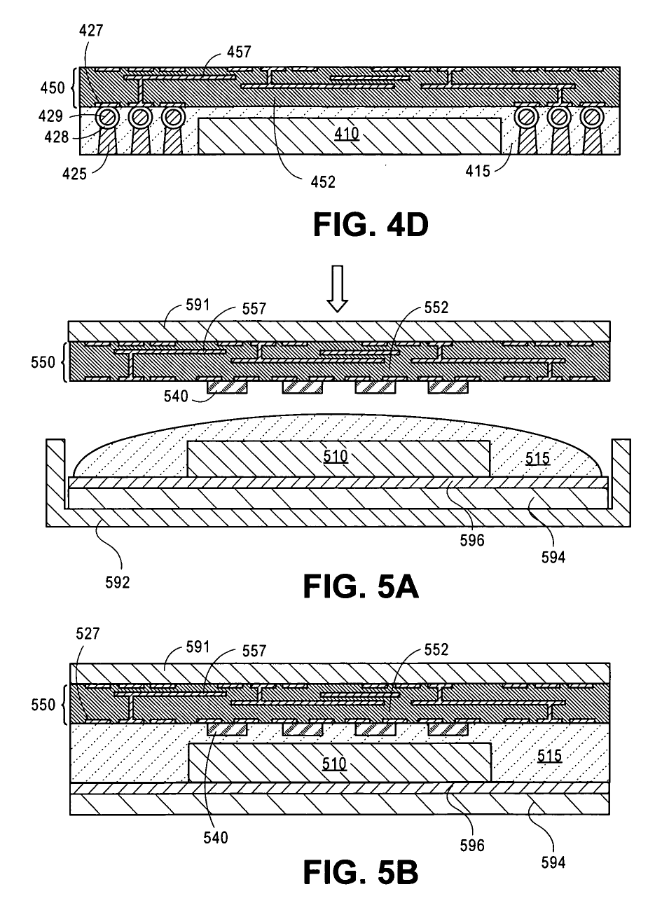

According to additional embodiments of the invention, the molding process may also be used to embed conductive balls into the mold layer when the substrate is attached. A process according to such an embodiment is illustrated and described with respect to FIGS. 4A-4D.

Referring now to FIG. 4A, a cross-sectional illustration of a molding tool used for attaching a substrate while forming the mold layer is shown according to an embodiment of the invention. The molding tool may be substantially similar to the molding tool illustrated and described in FIG. 3A, and therefore will not be described in detail here. However, it is to be appreciated that the substrate 450 that is held on the upper portion 491 of the molding tool may also include a plurality of conductive balls 428 that are attached to the contacts 427 formed on the bottom surface of the substrate 450. The conductive balls 428 may be any suitable conductive material. For example, the conductive balls 428 may be solder balls. Additional embodiments of the invention may include conductive balls 428 that have a core 429, as is shown in FIG. 4A. The core 429 may be a conductive or non-conductive material. For example, a solder ball may have a copper core or a polymer core. Furthermore, while the conductive balls 429 are illustrated as being substantially round, it is to be appreciated that any shaped conductive element may be used. Additional embodiments may replace the conductive balls 429 with conductive pillars (e.g., copper pillars). In some embodiments conductive pillars may be substantially the same thickness as the mold layer 415 that will be formed during the molding process. In such embodiments the laser drilled via openings may not be necessary.

Referring now to FIG. 4B, a cross-sectional illustration of the package after the substrate 450 is attached to the mold layer 415 is shown according to an embodiment of the invention. As illustrated, the conductive balls 428 may be embedded in the mold layer 415.

Referring now to FIG. 4C, a cross-sectional illustration of the package after the mold carrier 494 and the adhesive 496 are removed and via openings 424 are formed is shown according to an embodiment of the invention. The use of conductive balls 428 provides several benefits. One benefit is that the laser drilled via openings 424 do not need to be as deep. As such, the throughput can be increased because the reduced drill depth reduces the time needed to form the via openings. Additionally, the shallower openings are easier to fill with conductive material. Accordingly, the yield may be increased because the openings are more likely to be properly filled with conductive material. Furthermore, the shallower drill depth allows for the via openings 424 to be formed with a tighter pitch. Reducing the pitch allows for a decrease in the size of the package.

Referring now to FIG. 4D, a cross-sectional illustration of the package after the via openings are filled with a conductive material to form vias 425 is shown according to an embodiment of the invention. For example, the via openings 424 may be filled with any suitable deposition processes known in the art, such as electroplating, electroless plating, sputtering, printing, jetting, or any combination thereof. After the formation of the vias 425, the processing may proceed in substantially the same manner described above with respect to FIGS. 3F-3G, and therefore, will not be repeated here. It is to be appreciated that after the formation of the redistribution layer on the bottom surface of the mold layer 415 and the attachment of one or more components and solder bumps, a device substantially similar to the one illustrated in FIG. 2B may be formed.

According to additional embodiments of the invention, the molding process may also be used to embed one or more components into the mold layer when the substrate is attached. A process according to such an embodiment is illustrated and described with respect to FIGS. 5A-5B.

Referring now to FIG. 5A, a cross-sectional illustration of a molding tool used for attaching a substrate while forming the mold layer is shown according to an embodiment of the invention. The molding tool may be substantially similar to the molding tool illustrated and described in FIG. 3A, and therefore will not be described in detail here. However, it is to be appreciated that the substrate 550 that is held on the upper portion 591 of the molding tool may also include one or more additional components 540. The additional components 540 may be electrically coupled to the pads formed on a bottom surface of the substrate 550. By way of example, the additional components may be passive devices or active devices.

Referring now to FIG. 5B, a cross-sectional illustration of the package after the substrate 550 is attached to the mold layer 515 is shown according to an embodiment of the invention. As illustrated, the additional components 540 may be embedded in the mold layer 515. Positioning components on the bottom surface of the substrate 550 so that they are embedded in the mold layer provides additional surface area on the top surface of the substrate for attaching needed components. As such, more components may be included than would otherwise be possible. Additional embodiments of the invention may include a package that has all components 540 formed on the bottom surface of the substrate 550 and embedded in the mold layer 515. By relocating components 540 from the top surface of the substrate 550 to the bottom surface of the substrate 550, the overall thickness of the package may be decreased.

After the formation of the mold layer 515 with the additional components 540 embedded therein, the processing may proceed in substantially the same manner described above with respect to FIGS. 3C-3G, and therefore, will not be repeated here. It is to be appreciated that after the formation of the redistribution layer on the bottom surface of the mold layer 515 and the attachment of one or more components and solder bumps, a device substantially similar to the one illustrated in FIG. 2C may be formed.

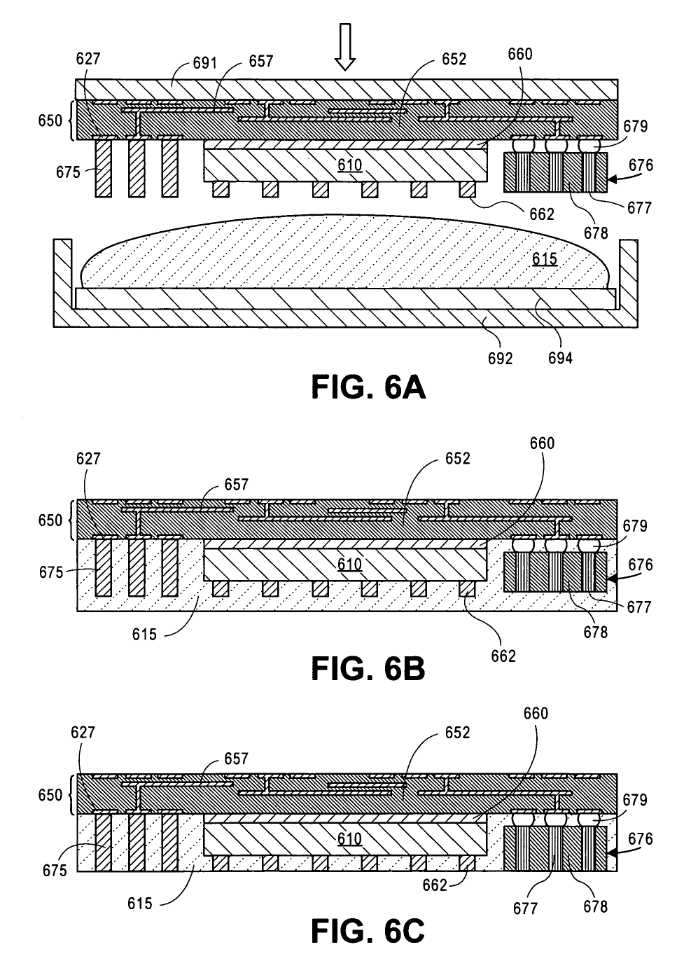

According to additional embodiments of the invention, a molding process may also be used that includes a die that is attached to the bottom surface the substrate prior to the molding process. A process according to such an embodiment is illustrated and described with respect to FIGS. 6A-6C.

Referring now to FIG. 6A, a cross-sectional illustration of a molding tool used for attaching a substrate while forming the mold layer is shown according to an embodiment of the invention. The molding tool may be substantially similar to the molding tool illustrated and described in FIG. 3A, and therefore will not be described in detail here. However, it is to be appreciated that the die 610 may be mounted to the substrate 650 prior to forming the mold layer 615. In one embodiment, the die 610 may be mounted to the substrate 650 with an adhesive 660. In an embodiment, the die 610 is mounted to the substrate 650 with an active side of the die 610 facing away from the substrate 650. Furthermore, embodiments of the invention may include a die 610 that also includes a plurality of conductive pillars 662. By way of example, the conductive pillars may be copper pillars. The conductive pillars 662 may be used to provide electrical connections to the active circuitry within the die 610. Additional embodiments of the invention may also include a plurality of conductive pillars 675 that are attached to the contacts 627 formed on the bottom surface of the substrate 650. The conductive pillars 675 may be any suitable conductive material. For example, the conductive pillars 675 and 662 may both be formed with electroplating or the like. Additionally, some embodiments may include one or more via bars 676 that are coupled to pads 627 by solder bumps 679. For example, the via bars 676 may be dielectric or silicon interposers 678 with conductive vias 677 formed through the thickness of the interposer 678. Since the die 610 is mounted to the substrate 650, embodiments of the invention may include a mold carrier 694 that does not have any components attached to it prior to forming the mold layer 615.

Referring now to FIG. 6B, a cross-sectional illustration of the package after the mold layer 615 is formed and removed from the mold carrier 694 is shown according to an embodiment of the invention. In some embodiments, the mold layer 615 may have a thickness that completely embeds the conductive pillars 662, 675 and the conductive via bars 676. Embodiments of the invention that have a mold layer 615 that completely embeds the conductive pillars 662, 675 and the conductive via bars 676 may include a mold layer recessing process that removes a bottom portion of the mold layer 615 in order to expose a surface of the conductive pillars 662, 675 and the surface of the conductive via bars 676. For example, the mold layer 615 may be recessed with a polishing operation or the mold layer 615 may be recessed with a laser drilling process.

Referring now to FIG. 6C, a cross-sectional illustration of the package after the mold layer has been recessed is shown according to an embodiment of the invention. While FIGS. 6A-6C illustrate vias formed with conductive via bars 675 and pillars 675, embodiments of the invention may omit the via bars 675, the pillars 675, or both features. In such an embodiment, through mold vias may be formed with any suitable drilling and plating process, similar to those described above.

After the formation of the conductive via bars 676 and the conductive pillars 662, 675 are exposed, the processing may proceed in substantially the same manner described above with respect to FIGS. 3F-3G, and therefore, will not be repeated here. It is to be appreciated that after the formation of the redistribution layer on the bottom surface of the mold layer 615 and the attachment of one or more components and solder bumps, a device substantially similar to the one illustrated in FIG. 2D may be formed.

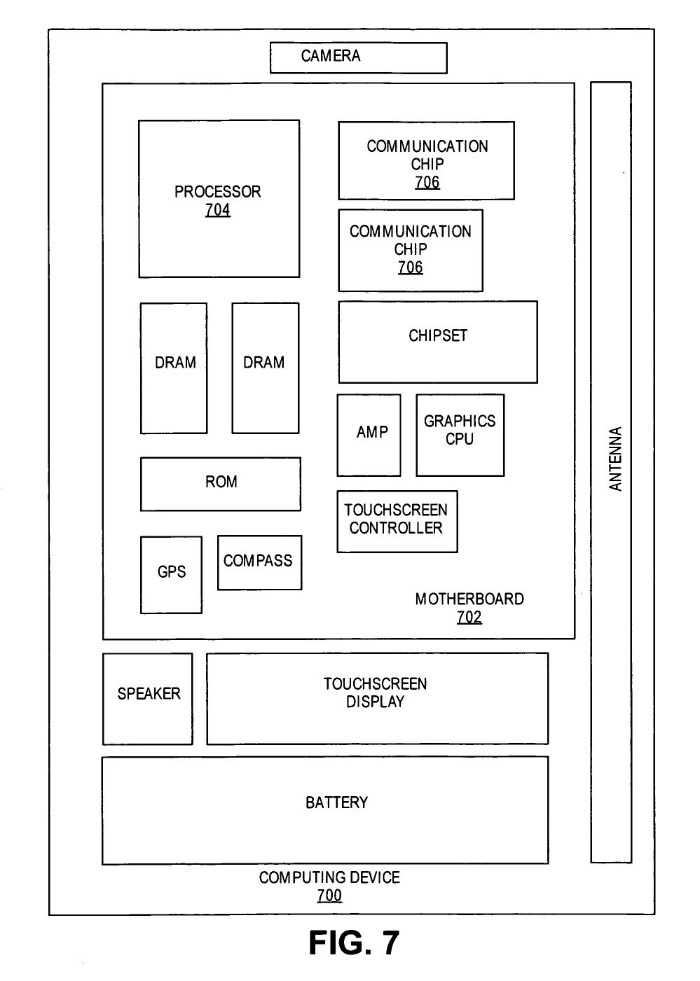

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor includes one or more devices that are assembled in an ePLB or eWLB based PoP package that that includes a mold layer directly contacting a substrate, in accordance with implementations of the invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip includes one or more devices that are assembled in an ePLB or eWLB based PoP package that that includes a mold layer directly contacting a substrate, in accordance with implementations of the invention.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Embodiments of the invention include a semiconductor package, comprising: a die embedded within a mold layer; a substrate positioned above the mold layer, wherein a surface of the substrate directly contacts a surface of the mold layer, and wherein an active side of the die faces away from the substrate; and a through mold via formed through the mold layer, wherein the through mold via is electrically coupled to a contact formed on the surface of the substrate that is contacting the mold layer.

Additional embodiments of the invention include a semiconductor package, further comprising: a conductive structure that electrically couples the through mold via to the contact, and wherein the conductive structure is embedded in the mold layer.

Additional embodiments of the invention include a semiconductor package, wherein the conductive structure is a solder ball.

Additional embodiments of the invention include a semiconductor package, wherein the solder ball has a core.

Additional embodiments of the invention include a semiconductor package, wherein the core is a polymer core or a copper core.

Additional embodiments of the invention include a semiconductor package, wherein one or more components are mounted to the surface of the substrate that is contacting the mold layer, and wherein the one or more components are embedded in the mold layer.

Additional embodiments of the invention include a semiconductor package, wherein the die is mounted to the substrate with an adhesive layer.

Additional embodiments of the invention include a semiconductor package, wherein the die comprises one or more pillars that provide an electrical connection from the die to a surface of the mold layer that faces away from the substrate.

Additional embodiments of the invention include a semiconductor package, wherein one or more components are mounted to a surface of the substrate facing away from the mold layer, and wherein at least one of the components is electrically coupled to the through mold via by conductive traces and vias formed in the substrate.

Additional embodiments of the invention include a semiconductor package, wherein at least one of the components is a high bandwidth memory.

Embodiments of the invention include a method of forming semiconductor package, comprising: dispensing a molding material over a die positioned on a mold carrier; pressing a substrate into the molding material and curing the molding material to form a mold layer around the die, wherein the substrate is adhered to the mold layer; removing the mold carrier form the mold layer; forming a via opening in the mold layer; and depositing a conductive material in the via opening to form a through mold via that is electrically coupled to a contact formed on the substrate.

Additional embodiments of the invention include a method of forming semiconductor package, wherein the via opening exposes the contact formed on the substrate.

Additional embodiments of the invention include a method of forming semiconductor package, wherein a conductive structure is attached to the contact formed on the substrate prior to pressing the substrate into the molding material, and wherein the conductive structure is embedded in the mold layer after the molding material is cured.

Additional embodiments of the invention include a method of forming semiconductor package, wherein the via opening exposes the conductive structure, and wherein the conductive structure electrically couples the via to the contact formed on the substrate.

Additional embodiments of the invention include a method of forming semiconductor package, wherein the conductive structure is a solder ball.

Additional embodiments of the invention include a method of forming semiconductor package, wherein one or more components are attached to the substrate prior to pressing the substrate into the molding material, and wherein the one or more components are embedded in the mold layer after the molding material is cured.

Additional embodiments of the invention include a method of forming semiconductor package, wherein the via opening is formed with a laser drilling process.

Additional embodiments of the invention include a method of forming semiconductor package, wherein the laser is aligned for the drilling process by using the die as a reference.

Additional embodiments of the invention include a method of forming semiconductor package, further comprising: attaching a component to a surface of the substrate opposite from the surface adhered to the mold layer, wherein the component is electrically coupled to the through mold via by conductive traces and vias formed in the substrate.

Additional embodiments of the invention include a method of forming semiconductor package, wherein the component is a high bandwidth memory.

Embodiments of the invention include a method of forming semiconductor package, comprising: dispensing a molding material over a mold carrier; pressing a substrate that has a die attached to the surface of the substrate into the molding material and curing the molding material to form a mold layer around the die, wherein the substrate is adhered to the mold layer, and wherein the die is embedded in the mold layer; removing the mold carrier form the mold layer; forming a via opening in the mold layer; and depositing a conductive material in the via opening to form a through mold via that is electrically coupled to a contact formed on the substrate.

Additional embodiments of the invention include a method of forming semiconductor package, wherein a plurality of conductive pillars are mounted to a surface of the die facing away from the substrate.

Additional embodiments of the invention include a method of forming semiconductor package, further comprising: recessing the mold layer to expose a surface of the conductive pillars.

Embodiments of the invention include a semiconductor package, comprising: a die embedded within a mold layer; a substrate positioned over the mold layer, wherein a surface of the substrate directly contacts a surface of the mold layer, and wherein an active side of the die faces away from the substrate; a through mold via formed through the mold layer, wherein the through mold via is electrically coupled to a contact formed on the surface of the substrate by a conductive structure that is contacting the mold layer; and one or more components mounted to the surface of the substrate that is contacting the mold layer, and wherein the one or more components are embedded in the mold layer.

Additional embodiments of the invention include a semiconductor package, wherein the conductive structure is a solder ball with a core that is copper or a polymer.

Additional embodiments of the invention include a semiconductor package, further comprising: one or more components mounted to a surface of the substrate facing away from the mold layer, and wherein at least one of the components is electrically coupled to the through mold via by conductive traces and vias formed in the substrate, and wherein at least one of the components is a high bandwidth memory.

1. A semiconductor package, comprising:
a die embedded within a mold layer;
a substrate positioned above the mold layer, wherein a surface of the substrate directly contacts a surface of the mold layer, and wherein an active side of the die faces away from the substrate; and
a through mold via formed through the mold layer, wherein the through mold via is electrically coupled to a contact formed on the surface of the substrate that is contacting the mold layer.

2. The semiconductor package of claim 1, further comprising:
a conductive structure that electrically couples the through mold via to the contact, and wherein the conductive structure is embedded in the mold layer.

3. The semiconductor package of claim 2, wherein the conductive structure is a solder ball.

4. The semiconductor package of claim 3, wherein the solder ball has a core.

5. The semiconductor package of claim 4, wherein the core is a polymer core or a copper core.

6. The semiconductor package of claim 1, wherein one or more components are mounted to the surface of the substrate that is contacting the mold layer, and wherein the one or more components are embedded in the mold layer.

7. The semiconductor package of claim 1, wherein the die is mounted to the substrate with an adhesive layer.

8. The semiconductor package of claim 7, wherein the die comprises one or more pillars that provide an electrical connection from the die to a surface of the mold layer that faces away from the substrate.

9. The semiconductor package of claim 1, wherein one or more components are mounted to a surface of the substrate facing away from the mold layer, and wherein at least one of the components is electrically coupled to the through mold via by conductive traces and vias formed in the substrate.

10. The semiconductor package of claim 1, wherein at least one of the components is a high bandwidth memory.

11. A method of forming semiconductor package, comprising:
dispensing a molding material over a die positioned on a mold carrier;
pressing a substrate into the molding material and curing the molding material to form a mold layer around the die, wherein the substrate is adhered to the mold layer;
removing the mold carrier form the mold layer;
forming a via opening in the mold layer; and
depositing a conductive material in the via opening to form a through mold via that is electrically coupled to a contact formed on the substrate.

12. The method of claim 11, wherein the via opening exposes the contact formed on the substrate.

13. The method of claim 11, wherein a conductive structure is attached to the contact formed on the substrate prior to pressing the substrate into the molding material, and wherein the conductive structure is embedded in the mold layer after the molding material is cured.

14. The method of claim 13, wherein the via opening exposes the conductive structure, and wherein the conductive structure electrically couples the via to the contact formed on the substrate.

15. The method of claim 14, wherein the conductive structure is a solder ball.

16. The method of claim 11, wherein one or more components are attached to the substrate prior to pressing the substrate into the molding material, and wherein the one or more components are embedded in the mold layer after the molding material is cured.

17. The method of claim 11, wherein the via opening is formed with a laser drilling process.

18. The method of claim 17, wherein the laser is aligned for the drilling process by using the die as a reference.

19. The method of claim 11, further comprising:
attaching a component to a surface of the substrate opposite from the surface adhered to the mold layer, wherein the component is electrically coupled to the through mold via by conductive traces and vias formed in the substrate.

20. The method of claim 19, wherein the component is a high bandwidth memory.

21. A method of forming semiconductor package, comprising:
dispensing a molding material over a mold carrier;
pressing a substrate that has a die attached to the surface of the substrate into the molding material and curing the molding material to form a mold layer around the die, wherein the substrate is adhered to the mold layer, and wherein the die is embedded in the mold layer;
removing the mold carrier form the mold layer;
forming a via opening in the mold layer; and
depositing a conductive material in the via opening to form a through mold via that is electrically coupled to a contact formed on the substrate.

22. The method of claim 21, wherein a plurality of conductive pillars are mounted to a surface of the die facing away from the substrate.

23. The method of claim 22, further comprising:
recessing the mold layer to expose a surface of the conductive pillars.

24. A semiconductor package, comprising:
a die embedded within a mold layer;
a substrate positioned over the mold layer, wherein a surface of the substrate directly contacts a surface of the mold layer, and wherein an active side of the die faces away from the substrate;
a through mold via formed through the mold layer, wherein the through mold via is electrically coupled to a contact formed on the surface of the substrate by a conductive structure that is contacting the mold layer; and
one or more components mounted to the surface of the substrate that is contacting the mold layer, and wherein the one or more components are embedded in the mold layer.

25. The semiconductor package of claim 24, wherein the conductive structure is a solder ball with a core that is copper or a polymer.

26. The semiconductor package of claim 24, further comprising:
one or more components mounted to a surface of the substrate facing away from the mold layer, and wherein at least one of the components is electrically coupled to the through mold via by conductive traces and vias formed in the substrate, and wherein at least one of the components is a high bandwidth memory.
